(19) United States
(12) Patent Application Publication
(10) Pub. No.: US 2025/0284018 A1
(43) Pub. Date: Sep. 11, 2025

(54) Integrated Seismic Data Augmentation

(71) Applicant: Saudi Arabian Oil Company, Dhahran (SA)

(72) Inventors: Tong Zhou, Beijing (CN); Yue Ma, Beijing (CN); Abdulmohsen M. Ali, Dammam (SA)

(21) Appl. No.: 18/596,111

(22) Filed: Mar. 5, 2024

(51) Int. Cl. G01V 1/50; G06F 30/20

(52) U.S. Cl. CPC G01V 1/50; G06F 30/20; G01V 2210/6222; G01V 2210/66

(57) ABSTRACT

A computer implemented method that enables integrated seismic data augmentation is described. The method includes generating a three-dimensional (3D) seismic velocity model using sequential gaussian simulation. The method includes executing forward modeling simulations on the seismic velocity model to generate primaries and multiples of wavelets associated with the seismic velocity model. Additionally, the method includes combining the primaries and the multiples of wavelets with noise to generate augmented seismic data.

### TECHNICAL FIELD

This disclosure relates generally to integrated seismic data augmentation.

### BACKGROUND

Deep learning enables understanding data and a predictive capability by learning relationships embedded in data. Deep learning can increase seismic data processing capabilities by training models with high-quality, varied training data.

### BRIEF DESCRIPTION OF DRAWINGS

FIG. 1 shows a workflow that enables integrated seismic data augmentation.

FIG. 2 shows well log sample points.

FIG. 3 shows sequential Gaussian simulation.

FIG. 4 shows velocity models and profiles.

FIG. 5 is a process flow diagram of a process that enables integrated seismic data augmentation.

FIG. 6 illustrates hydrocarbon production operations that include both one or more field operations and one or more computational operations, which exchange information and control exploration for the production of hydrocarbons.

FIG. 7 is a schematic illustration of an example controller (or control system) for that enables integrated seismic data augmentation.

### DETAILED DESCRIPTION

Exploration seismology involves prospecting for energy sources, such as oil and gas. For example, exploration seismology uses artificially generated elastic waves to locate mineral deposits, such as including hydrocarbons, ores, water, geothermal reservoirs, etc., and to obtain geological information for engineering. The waves may be that transmitted by P-waves and S-waves, in the frequency range of approximately 1 to 100 Hz. The waves enable interpretation of the composition, fluid content, extent, and geometry of rocks in the subsurface. Exploration seismology provides data that, when used in conjunction with other geophysical, borehole, and geological data and with concepts of physics and geology, can provide information about the structure and distribution of rock types. The data provided from exploration seismology includes noise, scattering, fluctuations, etc. Exploration seismology tasks, such as seismic denoising, data reconstruction, horizon/fault detection, and lithology prediction can be improved or automated by deep learning based techniques. The success of deep learning based techniques depends on, at least in part, the quality of the training data, the variety of the training data, and the amount of training data. Traditionally, training data associated with exploration seismology is low quality, with little to no variety. Further, this training data can be challenging to obtain due to confidentiality of exploration seismology data. In some cases, synthetic or augmented seismic data is generated to train neural networks that perform exploration seismology tasks. Traditional synthetic seismic data lacks realistic noise, scattering, fluctuations, and the like, which leads to poor transfer ability of the trained neural network.

Embodiments described herein enable integrated seismic data augmentation. In some embodiments, seismic data is generated from existing well logs and seismic images. Seismic scattering caused by stochastic media, multiples, and wavelet fluctuations is determined from the well logs and seismic images. Image guided interpolation, sequential gaussian simulation, and multiple forward simulation techniques are executed in parallel to generate high-quality, realistic seismic data augmentations. In some embodiments, the augmented seismic data includes scatterings and fluctuations that render the augmented seismic data indistinguishable from genuine seismic data captured before, during, or after real-world drilling operations.

Some advantages of the present techniques include an improvement to exploration seismology tasks, such as seismic denoising, data reconstruction, horizon/fault detection, and lithology prediction by providing realistic training data. The realistic training data is used to train one or more neural networks to perform an exploration seismology task. The high-quality, realistic, augmented seismic data enables training of neural networks and improving the generalization abilities of the trained neural networks. In examples, preprocessing the well logs using image-guided interpolation ensures that a threshold amount of well log data points are available for sequential Gaussian simulation.

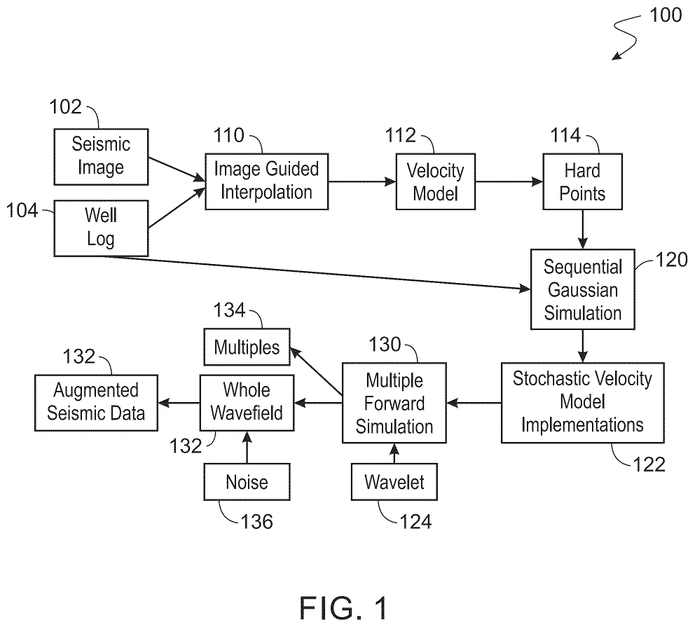

FIG. 1 shows a workflow 100 that enables integrated seismic data augmentation. As shown in FIG. 1, seismic images are represented at block 102, well logs are represented at block 104. The workflow 100 includes image-guided interpolation (IGI) at block 110, sequential Gaussian simulation (SGS) at block 120, and reflectivity forward simulation at block 130. In the image-guided interpolation at block 110, well log sample points are interpolated to generate three-dimensional (3D) gridded data according to the structure of the seismic image. In examples, the 3D gridded data forms a geophysical model of the subsurface with cells that correspond to respective locations of the subsurface and are associated with at least one value. The model is created by evaluating the value associated with each cell and modifying or retaining the value based on a predetermined series of rules. In examples, the value associated with each cell is determined on a cell-by-cell basis, where calculations for each cell use the value of the respective cell, the manipulation that is being applied, and other cell locations to include in the calculations.

In some embodiments, the well log sample points are seismic velocity log data points and density log data points. In sequential Gaussian simulation at block 120, stochastic implementations of the seismic velocity model are generated. The generated implementations preserve the general features of the IGI-generated gridded data and are fit to the variogram of the IGI-generated gridded data. In the reflectivity forward simulation at block 130, the seismic velocity model is used to model the primary reflections (e.g., primaries) and multiple reflections (e.g., multiples). In examples, primaries are seismic events whose energy has been reflected once. Multiples, by contrast, are events whose energy has been reflected more than once. In examples, the present techniques enable augmented seismic data that includes scatterings based on realistic primaries and multiples that render the augmented seismic data indistinguishable from genuine seismic data.

In the example of FIG. 1, inputs are shown by the seismic images at block 102, the well logs at block 104, wavelet at block 124, and noise at block 136. The output of the workflow is the augmented seismic data at block 132. Intermediate results of the workflow 100 are the velocity model at block 112, hard points at block 114, stochastic velocity model implementations at block 122, wavefield at block 132, and multiples at block 134. In some embodiments, the intermediate results are used as training data for neural networks.

For the image guided interpolation at block 110, well log data (104) and seismic images (102) are obtained as input. The well log (104) data includes well log sample points (depth and seismic velocity). The seismic images (102) include seismic images after migration and time-depth conversion. The output of image guided interpolation at block 110 is a deterministic interpolated seismic velocity model (112). In examples, the seismic images are uniformly sampled images of geologic structures, and they spatially cover a large area as opposed to well log data, which are often scattered sparsely and are associated with a particular borehole (e.g., a small area). Well log data points are interpolated from the boreholes (e.g., where the well logs are captured) onto the seismic image grid.

For the image guided interpolation at block 110, blended neighbor interpolation is performed by extracting structural information that guides the interpolation from a seismic image. The structural information is represented by metric tensors constrained by interpreted horizons as well as the seismic image.

For the image guided interpolation at block 110, the eikonal equation is solved as follows:

$$∇ t ( x ) \cdot D ( x ) ∇ t ( x ) = 1 , x ∉ χ ; \qquad ( 1 )$$

$$where$$

$$t ( {x}_{k} ) = 0 , {x}_{k} ∈ χ \qquad ( 2 )$$

and where t (x) is the minimal time from point x to the nearest well log sample point xₖ·X is the set of well log sample points. D(x) is a metric tensor computed from a seismic image. The metric tensor controls how neighborhood information is guided in the interpolation of each point. Blended neighbor interpolation is performed by solving the blending equation as follows:

$$q ( x ) - \frac{1}{2} ∇ \cdot {t}^{2} ( x ) D ( x ) ∇ q ( x ) = p ( x ) \qquad ( 3 )$$

where p(x) is the nearest neighbor interpolation and q(x) is the output image-guided blended neighbor interpolation. The image guided interpolation effectively interpolates sparse well log sample points to the 3D gridded seismic velocity model, and preserving geological structures constrained by seismic image.

The velocity model at block 112 and hard points 114 are input to the sequential Gaussian simulation at block 120. In examples, the hard points are well log data sample points generated by the image guided interpolation at block 110. In examples, the well logs contain dense data such that sequential Gaussian simulation is performed directly with well logs as hard data. However, well logs can be sparse, so in examples image guided interpolation generate a major portion of hard data for sequential Gaussian simulation.

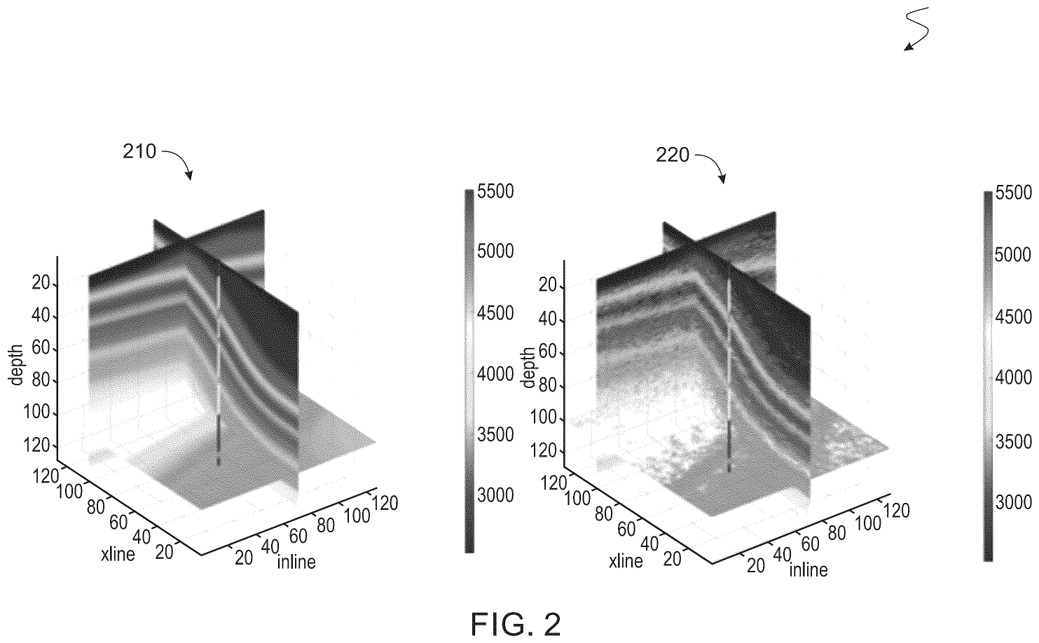

Well log sample points are shown in FIG. 2. In particular, at reference number 210, a 3D reference seismic velocity model after IGI and with well logs is shown. The 3D reference seismic velocity model after IGI and with well logs is input to the sequential Gaussian simulation at block 120. At reference number 220 of FIG. 2, the output of the sequential Gaussian simulation at block 120 is shown as a stochastic implementation of the seismic velocity. The stochastic implementation of the seismic velocity at reference number 220 preserves features from the IGI but with random scatterers complying with the distribution of the original seismic data. Accordingly, the output of the sequential Gaussian simulation at block 120 are stochastic seismic velocity implementations. In examples, the output stochastic seismic velocity implementations are variations of the same seismic velocity model, with varying noise, scatterings, and fluctuations. The IGI image (e.g., reference number 210) is used to add hard data along with the well logs for sequential Gaussian simulation. In some embodiments, the well log sample points are dense so that the sequential Gaussian simulation at block 120 is performed directly on the dense well log sample points.

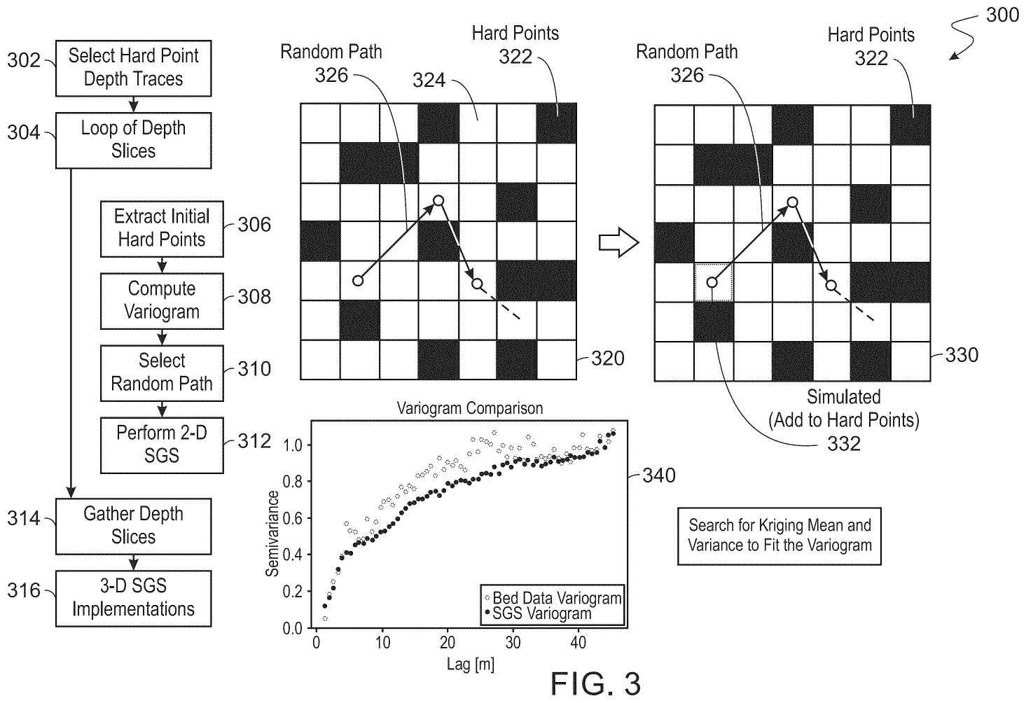

FIG. 3 is a workflow 300 that enables 3D sequential Gaussian simulation. FIG. 3 also shows 2D sequential Gaussian simulation, which first computes kriging mean and variance which fits the variogram (340) of the hard data to get the probabilistic distribution of the interpolated data point (e.g., the current data point to be interpolated), and then sample the interpolated data point from the distribution. At block 302, hard point depth traces are selected. In some embodiments, hard points are randomly selected in 2D to obtain x, y coordinates. Each selected hard point is extended along the z direction to get hard point depth traces. In some embodiments, data points are randomly selected from the IGI result (e.g., velocity model at block 112), along with all the well log sample points (e.g., hard points) as the hard data set (e.g., hard points including randomly selected data points from IGI image and well log). At block 304, depth slices are iteratively simulated. In particular, the workflow 300 loops from each depth to perform 2D sequential Gaussian simulation as shown at blocks 306, 308, 310, and 312. At block 306, initial hard points are extracted. The hard data is transferred to a Gaussian distribution, and a variogram of the hard data is computed at block 308. At block 310, a random path of the simulation points is selected. The random path 326 and hard points 322 are shown on a grid 320. At block 312, 2D sequential Gaussian simulation is performed on the random path. Grid 330 shows the interpolated point that is added to hard points.

In examples, grids 320 and 330 show a number of cells associated with data points. Black cells such as cell 322 represent hard points. White cells such as cell 324 represent points to be interpolated. Cell 332 of grid 330 represents a cell with an interpolated data point that is added to the hard point data set. For example, an ordinary Kriging mean and Kriging variance is estimated for the current interpolation point to fit the variogram of the hard data. The distribution is randomly sampled, and the current interpolation point is added to the hard data. The process moves to the next interpolation point, transferring back to the original distribution when all interpolation points are finished. At block 314, the 2D sequential Gaussian simulation results are combined at each depth together to output a 3D sequential Gaussian simulation implementation at block 316. The random sequential Gaussian simulation implementations retains the basic features of the geological structure and includes realistic features of the random fluctuations of the seismic velocity. Accordingly, the output of the sequential Gaussian simulation at block 120 is a stochastic implementation of the seismic velocity, preserving features from the IGI but with random scatterers complying with the distribution of the original seismic data.

Referring again to FIG. 1, at block 130, reflectivity forward simulation is applied to the random implementations of the seismic velocity model generated by the sequential Gaussian simulation at block 120. After sequential Gaussian simulation at block 120, each respective random implementation of the seismic velocity model is used to generate multiples and primaries of the reflection wavefield. For example, assuming the 3D velocity model implementations do not include high-angle tilted layers or large variations, the 3D velocity model is decomposed to one dimensional (1D) vertical profiles. The velocity traces are converted to reflectivity assuming a constant density. The 1D reflectivity forward modelling is applied trace-by-trace to generate primaries and multiples of a given wavelet (with input parameters wavelet shape, time sampling rate and recording length).

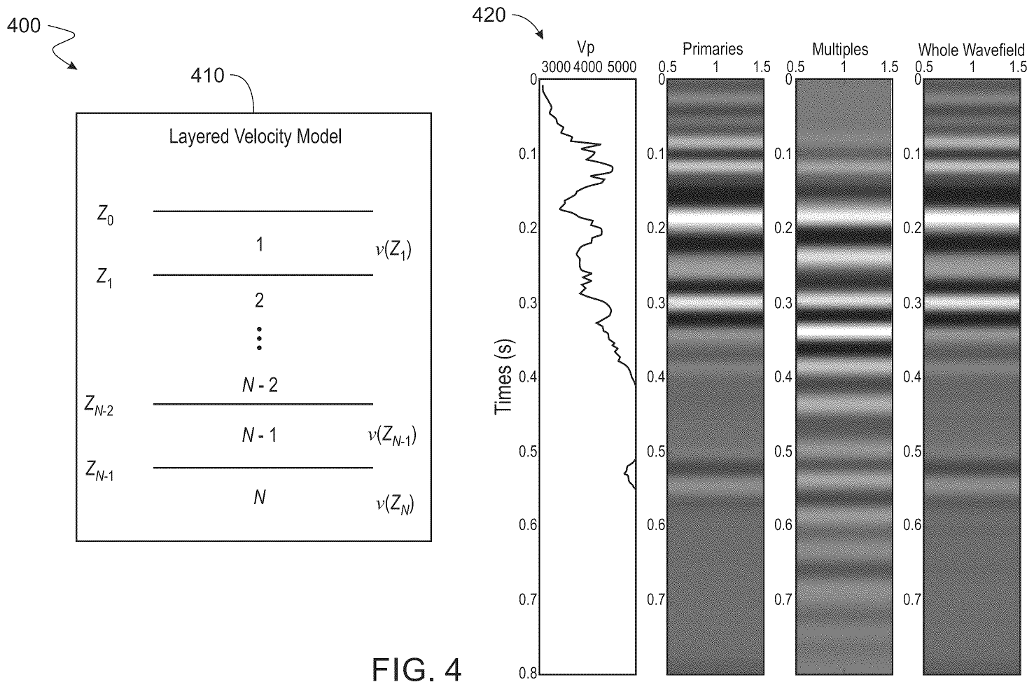

FIG. 4 shows velocity models and profiles. In the example of FIG. 4, reference number 410 shows a layered velocity model. Reference number 420 of FIG. 4 shows a seismic velocity profile, and generated primaries, multiples and the whole wavefield by the 1-D reflection forward modeling. The reflectivity forward modeling sums infinite order internal multiples thus captures the full properties of the multiple fields of the given reflectivity model. For example, given a 1D n-layer velocity model as shown in FIG. 4 at reference number 410, the reflection efficient is computed the bottom layer at depth z_{N-1}⁻ as follows:

$${R}_{D} ( {z}_{N - 1}^{-} ) = {r}_{d} ( {z}_{N - 1} ) . \qquad ( 4 )$$

Next compute the reflection below the interface at z_{N-2}⁺

$${R}_{D} ( {z}_{N - 2}^{+} ) = {E}_{D}^{N - 1} {R}_{D} ( {z}_{N - 1}^{-} ) {E}_{U}^{N - 1} , \qquad ( 5 )$$

where

$${E}_{D}^{N - 1} = {E}_{U}^{N - 1} = {e}^{i ω \frac{{z}_{N - 1} - {z}_{N - 2}}{v ( {z}_{N - 1} )}} . \qquad ( 6 )$$

Then compute the reflection above the interface at z_{N-2}⁻

$${R}_{D} ( {z}_{N - 2}^{-} ) = {r}_{d} ( {z}_{N - 2} ) + {t}_{d} ( {z}_{N - 2} ) {R}_{D} ( {z}_{N - 2}^{+} ) {( 1 - {r}_{u} ( {z}_{N - 2} ) {R}_{D} ( {z}_{N - 2}^{+} ) )}^{- 1} {t}_{u} ( {z}_{N - 2} ) = {r}_{N - 2} + ( 1 - {r}_{N - 2}^{2} ) {R}_{D} ( {z}_{N - 2}^{+} ) {( 1 + {r}_{N - 2} {R}_{D} ( {z}_{N - 2}^{+} ) )}^{- 1} . \qquad ( 7 )$$

Recursively computing equations (5)-(7) yields the reflection coefficients of each layer. The reflection coefficients are computed for the overall wavefield, and separate primaries and multiples. The reflection coefficients are convolved with the source wavelet to obtain the 1D seismic trace with multiples of the input 1D velocity profile. FIG. 4 at block 420 shows an example of 1D velocity profile, primaries, multiples and overall wavefield. Referring again to FIG. 1, the 1D traces of generated seismic data are combined with noise at block 136 to obtain the augmented seismic data 132. The augmented seismic data are new synthetic seismic images with multiples. The synthetic images are computed from models augmented from original seismic image and well log with additional scatterings, fluctuations, and noise.

In examples, the image-guided interpolation and sequential Gaussian simulation generate reliable velocity models with stochastic scatterers preserving the seismic horizons and well logs. The fault features are generally preserved but smoothed. The present techniques use wavelet fluctuation generation to fit the realistic spatial correlation pattern by a trial-and-error approach. In examples, wavelet fluctuation generation includes perturbing wavelets by adding a series of time delayed and weighted Gaussian functions which fits the spatial correlation of original field data. The reflectivity forward modelling approach can produce clear separated multiples and primaries, which enables a training data set with and without multiples. The generated synthetic seismic data contains realistic scattering features caused by random media.

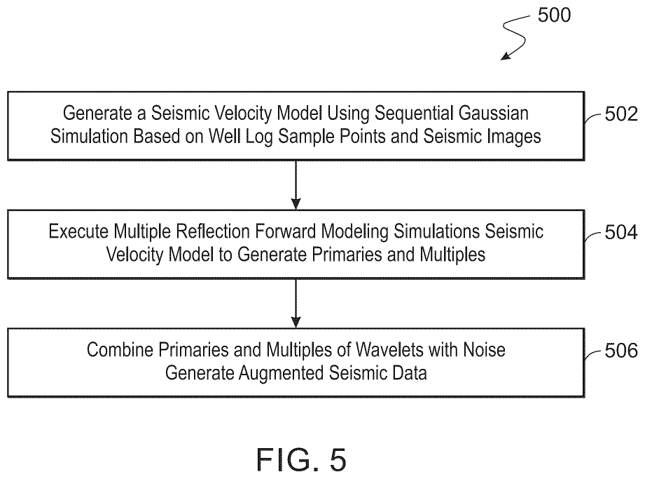

FIG. 5 is a process flow diagram of a process 500 that enables integrated seismic data augmentation.

At block 502, a seismic velocity model is generated using sequential gaussian simulation based on well log sample points and structure of a seismic image, wherein two-dimensional sequential gaussian simulation is iteratively performed using well log sample points and seismic images at respective depths. The two-dimensional sequential gaussian simulation results are combined to obtain a three-dimensional sequential gaussian simulation result.

At block 504, multiple reflection forward modeling simulations are executed on the stochastic seismic velocity models to generate primaries and multiples of wavelets associated with the stochastic seismic velocity models. In examples, the primaries and multiples of wavelets replicate seismic events that occur at one or more depths below the subsurface.

At block 506, the primaries and multiples of wavelets are combined with noise to generate augmented seismic data. In examples, the augmented seismic data is a realistic synthetic seismic dataset, used to train a high-quality deep learning neural network for multiple tasks in exploration seismology. The augmented seismic data includes scatterings, fluctuations of wavelets as well as multiples. The scatterings, fluctuations of wavelets as well as multiples add complexity and variety to the synthetic dataset and enable the trained neural network to distinguish seismic fluctuations and multiples rather than only random noise, which enhances the generalization ability of neural networks.

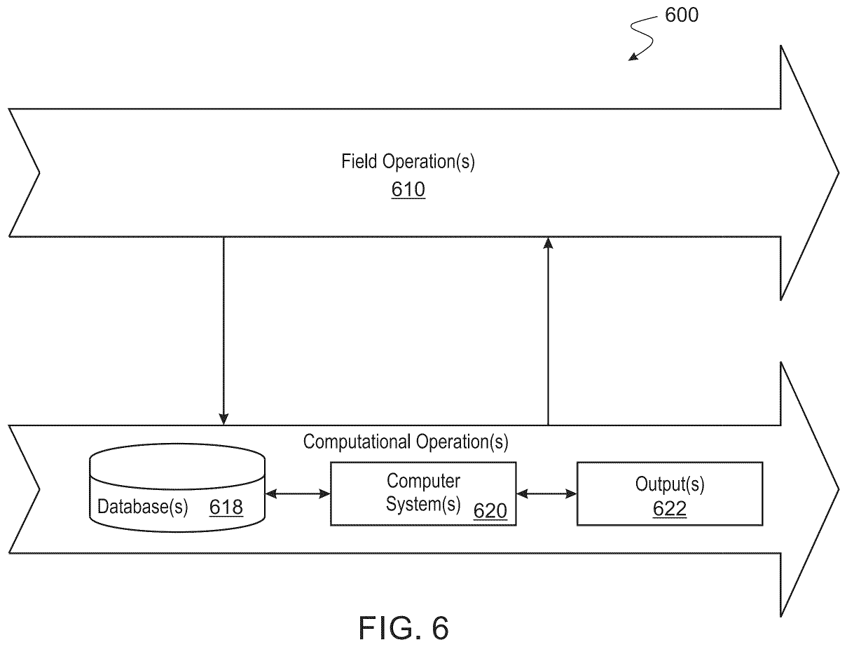

In some embodiments, the augmented seismic data is used to train machine learning models to output predictions or classifications based on the input data, such as well log sample points. The machine learning models output predictions or classifications that are used to implement or execute hydrocarbon production operations, such as the hydrocarbon production operations 600 of FIG. 6.

FIG. 6 illustrates hydrocarbon production operations 600 that include both one or more field operations 610 and one or more computational operations 612, which exchange information and control exploration for the production of hydrocarbons. In some implementations, outputs of techniques of the present disclosure can be performed before, during, or in combination with the hydrocarbon production operations 600, specifically, for example, either as field operations 610 or computational operations 612, or both.

Examples of field operations 610 include forming/drilling a wellbore, hydraulic fracturing, producing through the wellbore, injecting fluids (such as water) through the wellbore, to name a few. In some implementations, methods of the present disclosure can trigger or control the field operations 610. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 610 and responsively triggering the field operations 610 including, for example, generating plans and signals that provide feedback to and control physical components of the field operations 610. Alternatively or in addition, the field operations 610 can trigger the methods of the present disclosure. For example, implementing physical components (including, for example, hardware, such as sensors) deployed in the field operations 610 can generate plans and signals that can be provided as input or feedback (or both) to the methods of the present disclosure.

Examples of computational operations 612 include one or more computer systems 620 that include one or more processors and computer-readable media (e.g., non-transitory computer-readable media) operatively coupled to the one or more processors to execute computer operations to perform the methods of the present disclosure. The computational operations 612 can be implemented using one or more databases 618, which store data received from the field operations 610 and/or generated internally within the computational operations 612 (e.g., by implementing the methods of the present disclosure) or both. For example, the one or more computer systems 620 process inputs from the field operations 610 to assess conditions in the physical world, the outputs of which are stored in the databases 618. For example, seismic sensors of the field operations 610 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 612 where they are stored in the databases 618 and analyzed by the one or more computer systems 620.

In some implementations, one or more outputs 622 generated by the one or more computer systems 620 can be provided as feedback/input to the field operations 610 (either as direct input or stored in the databases 618). The field operations 610 can use the feedback/input to control physical components used to perform the field operations 610 in the real world.

For example, the computational operations 612 can process the seismic data to generate three-dimensional (3D) maps of the subsurface formation. The computational operations 612 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 612 to process new information about the formation and control the drilling to adjust to the observed conditions in real-time.

The one or more computer systems 620 can update the 3D maps of the subsurface formation as information from one exploration well is received and the computational operations 612 can adjust the location of the next exploration well based on the updated 3D maps. Similarly, the data received from production operations can be used by the computational operations 612 to control components of the production operations. For example, production well and pipeline data can be analyzed to predict slugging in pipelines leading to a refinery and the computational operations 612 can control machine operated valves upstream of the refinery to reduce the likelihood of plant disruptions that run the risk of taking the plant offline.

In some implementations of the computational operations 612, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

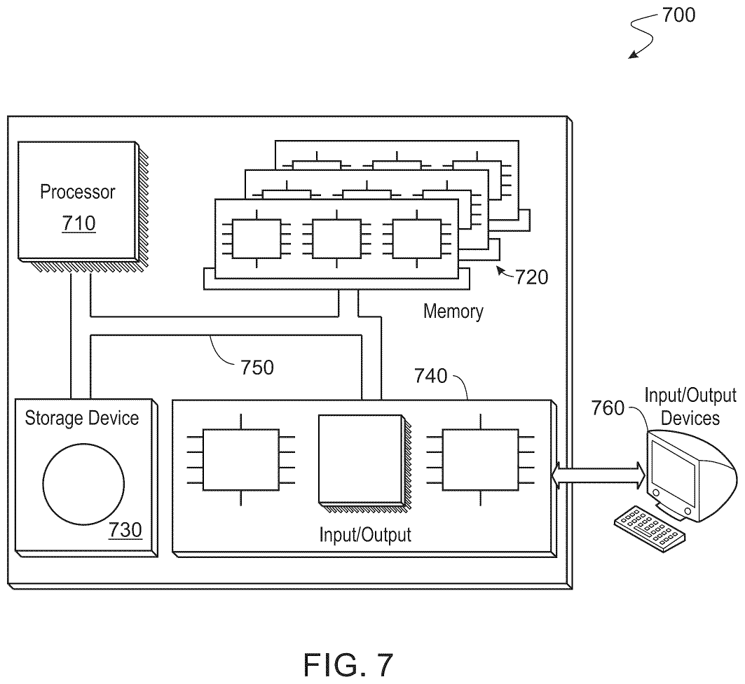

FIG. 7 is a schematic illustration of an example controller 700 (or control system) for that enables integrated seismic data augmentation. For example, the controller 700 may be operable according to the workflow 100 of FIG. 1 or the process 500 of FIG. 5. In some embodiments, the controller 700 is the same as or similar to the computer systems 620 of FIG. 6. The controller 700 is intended to include various forms of digital computers, such as printed circuit boards (PCB), processors, digital circuitry, or otherwise parts of a system for supply chain alert management. Additionally the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 700 includes a processor 710, a memory 720, a storage device 730, and an input/output interface 740 communicatively coupled with input/output devices 760 (for example, displays, keyboards, measurement devices, sensors, valves, pumps). Each of the components 710, 720, 730, and 740 are interconnected using a system bus 750. The processor 710 is capable of processing instructions for execution within the controller 700. The processor may be designed using any of a number of architectures. For example, the processor 710 may be a CISC (Complex Instruction Set Computers) processor, a RISC (Reduced Instruction Set Computer) processor, or a MISC (Minimal Instruction Set Computer) processor.

In one implementation, the processor 710 is a single-threaded processor. In another implementation, the processor 710 is a multi-threaded processor. The processor 710 is capable of processing instructions stored in the memory 720 or on the storage device 730 to display graphical information for a user interface on the input/output interface 740.

The memory 720 stores information within the controller 700. In one implementation, the memory 720 is a computer-readable medium. In one implementation, the memory 720 is a volatile memory unit. In another implementation, the memory 720 is a nonvolatile memory unit.

The storage device 730 is capable of providing mass storage for the controller 700. In one implementation, the storage device 730 is a computer-readable medium. In various different implementations, the storage device 730 may be a floppy disk device, a hard disk device, an optical disk device, or a tape device.

The input/output interface 740 provides input/output operations for the controller 700. In one implementation, the input/output devices 760 includes a keyboard and/or pointing device. In another implementation, the input/output devices 760 includes a display unit for displaying graphical user interfaces.

There can be any number of controllers 700 associated with, or external to, a computer system containing controller 700, with each controller 700 communicating over a network. Further, the terms “client,” “user,” and other appropriate terminology can be used interchangeably, as appropriate, without departing from the scope of the present disclosure. Moreover, the present disclosure contemplates that many users can use one controller 700 and one user can use multiple controllers 700.

### EMBODIMENTS

According to some non-limiting embodiments or examples, provided is a computer-implemented method that enables integrated seismic data augmentation, including: generating, using at least one hardware processor, a three-dimensional (3D) seismic velocity model using sequential gaussian simulation based on interpolated well log sample points and seismic images, wherein two-dimensional (2D) sequential gaussian simulation is iteratively performed at respective depths; executing, using the at least one hardware processor, forward modeling simulations on the seismic velocity model to generate primaries and multiples of wavelets associated with the seismic velocity model; and combining, using the at least one hardware processor, the primaries and the multiples of wavelets with noise to generate augmented seismic data.

According to some non-limiting embodiments or examples, provided is an apparatus including a non-transitory, computer readable, storage medium that stores instructions that, when executed by at least one processor, cause the at least one processor to perform operations including: generating a three-dimensional (3D) seismic velocity model using sequential gaussian simulation based on interpolated well log sample points and seismic images, wherein two-dimensional (2D) sequential gaussian simulation is iteratively performed at respective depths; executing forward modeling simulations on the seismic velocity model to generate primaries and multiples of wavelets associated with the seismic velocity model; and combining the primaries and the multiples of wavelets with noise to generate augmented seismic data.

According to some non-limiting embodiments or examples, provided is a system, including one or more memory modules; one or more hardware processors communicably coupled to the one or more memory modules, the one or more hardware processors configured to execute instructions stored on the one or more memory models to perform operations including: generating a three-dimensional (3D) seismic velocity model using sequential gaussian simulation based on interpolated well log sample points and seismic images, wherein two-dimensional (2D) sequential gaussian simulation is iteratively performed at respective depths; executing forward modeling simulations on the seismic velocity model to generate primaries and multiples of wavelets associated with the seismic velocity model; and combining the primaries and the multiples of wavelets with noise to generate augmented seismic data.

Further non-limiting aspects or embodiments are set forth in the following numbered embodiments:

Embodiment 1: A computer-implemented method that enables integrated seismic data augmentation, including: generating, using at least one hardware processor, a three-dimensional (3D) seismic velocity model using sequential gaussian simulation based on interpolated well log sample points and seismic images, wherein two-dimensional (2D) sequential gaussian simulation is iteratively performed at respective depths; executing, using the at least one hardware processor, forward modeling simulations on the seismic velocity model to generate primaries and multiples of wavelets associated with the seismic velocity model; and combining, using the at least one hardware processor, the primaries and the multiples of wavelets with noise to generate augmented seismic data.

Embodiment 2: The computer implemented method of embodiment 1, wherein the forward simulations are performed by summing reflections of velocity models generated by sequential gaussian simulation.

Embodiment 3: The computer implemented method of embodiment 1, including generating the interpolated well log sample points by performing image guided interpolation using the seismic images.

Embodiment 4: The computer implemented method of embodiment 1, wherein the interpolated well log sample points are generated by extracting structural information that guides the interpolation from a respective seismic image.

Embodiment 5: The computer implemented method of embodiment 1, wherein 2D sequential Gaussian simulation is performed by computing a kriging mean and variance to fit a variogram of hard data to obtain a probabilistic distribution of a respective simulation data point.

Embodiment 6: The computer implemented method of embodiment 1, wherein the results of iterative 2D sequential gaussian simulation are combined to obtain the 3D seismic velocity model.

Embodiment 7: The computer implemented method of embodiment 1, wherein the well log sample points are depth and seismic velocity data points.

Embodiment 8: An apparatus including a non-transitory, computer readable, storage medium that stores instructions that, when executed by at least one processor, cause the at least one processor to perform operations including: generating a three-dimensional (3D) seismic velocity model using sequential gaussian simulation based on interpolated well log sample points and seismic images, wherein two-dimensional (2D) sequential gaussian simulation is iteratively performed at respective depths; executing forward modeling simulations on the seismic velocity model to generate primaries and multiples of wavelets associated with the seismic velocity model; and combining the primaries and the multiples of wavelets with noise to generate augmented seismic data.

Embodiment 9: The apparatus of embodiment 8, wherein the forward simulations are performed by summing reflections of velocity models generated by sequential gaussian simulation.

Embodiment 10: The apparatus of embodiment 8, including generating the interpolated well log sample points by performing image guided interpolation using the seismic images.

Embodiment 11: The apparatus of embodiment 8, wherein the interpolated well log sample points are generated by extracting structural information that guides the interpolation from a respective seismic image.

Embodiment 12: The apparatus of embodiment 8, wherein 2D sequential Gaussian simulation is performed by computing a kriging mean and variance to fit a variogram of hard data to obtain a probabilistic distribution of a respective simulation data point.

Embodiment 13: The apparatus of embodiment 8, wherein the results of iterative 2D sequential gaussian simulation are combined to obtain the 3D seismic velocity model.

Embodiment 14: The apparatus of embodiment 8, wherein the well log sample points are depth and seismic velocity data points.

Embodiment 15: A system, including: one or more memory modules; one or more hardware processors communicably coupled to the one or more memory modules, the one or more hardware processors configured to execute instructions stored on the one or more memory models to perform operations including: generating a three-dimensional (3D) seismic velocity model using sequential gaussian simulation based on interpolated well log sample points and seismic images, wherein two-dimensional (2D) sequential gaussian simulation is iteratively performed at respective depths; executing forward modeling simulations on the seismic velocity model to generate primaries and multiples of wavelets associated with the seismic velocity model; and combining the primaries and the multiples of wavelets with noise to generate augmented seismic data.

Embodiment 16: The system of embodiment 15, wherein the forward simulations are performed by summing reflections of velocity models generated by sequential gaussian simulation.

Embodiment 17: The system of embodiment 15, including generating the interpolated well log sample points by performing image guided interpolation using the seismic images.

Embodiment 18: The system of embodiment 15, wherein the interpolated well log sample points are generated by extracting structural information that guides the interpolation from a respective seismic image.

Embodiment 19: The system of embodiment 15, wherein 2D sequential Gaussian simulation is performed by computing a kriging mean and variance to fit a variogram of hard data to obtain a probabilistic distribution of a respective simulation data point.

Embodiment 20: The system of embodiment 15, wherein the results of iterative 2D sequential gaussian simulation are combined to obtain the 3D seismic velocity model.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship. Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

What is claimed is:

1. A computer-implemented method that enables integrated seismic data augmentation, comprising:
generating, using at least one hardware processor, a three-dimensional (3D) seismic velocity model using sequential gaussian simulation based on interpolated well log sample points and seismic images, wherein two-dimensional (2D) sequential gaussian simulation is iteratively performed at respective depths;
executing, using the at least one hardware processor, forward modeling simulations on the seismic velocity model to generate primaries and multiples of wavelets associated with the seismic velocity model; and
combining, using the at least one hardware processor, the primaries and the multiples of wavelets with noise to generate augmented seismic data.

2. The computer implemented method of claim 1, wherein the forward simulations are performed by summing reflections of velocity models generated by sequential gaussian simulation.

3. The computer implemented method of claim 1, comprising generating the interpolated well log sample points by performing image guided interpolation using the seismic images.

4. The computer implemented method of claim 1, wherein the interpolated well log sample points are generated by extracting structural information that guides the interpolation from a respective seismic image.

5. The computer implemented method of claim 1, wherein 2D sequential Gaussian simulation is performed by computing a kriging mean and variance to fit a variogram of hard data to obtain a probabilistic distribution of a respective simulation data point.

6. The computer implemented method of claim 1, wherein results of iterative 2D sequential gaussian simulation are combined to obtain the 3D seismic velocity model.

7. The computer implemented method of claim 1, wherein the well log sample points are depth and seismic velocity data points.

8. An apparatus comprising a non-transitory, computer readable, storage medium that stores instructions that, when executed by at least one processor, cause the at least one processor to perform operations comprising:
generating a three-dimensional (3D) seismic velocity model using sequential gaussian simulation based on interpolated well log sample points and seismic images, wherein two-dimensional (2D) sequential gaussian simulation is iteratively performed at respective depths;
executing forward modeling simulations on the seismic velocity model to generate primaries and multiples of wavelets associated with the seismic velocity model; and
combining the primaries and the multiples of wavelets with noise to generate augmented seismic data.

9. The apparatus of claim 8, wherein the forward simulations are performed by summing reflections of velocity models generated by sequential gaussian simulation.

10. The apparatus of claim 8, comprising generating the interpolated well log sample points by performing image guided interpolation using the seismic images.

11. The apparatus of claim 8, wherein the interpolated well log sample points are generated by extracting structural information that guides the interpolation from a respective seismic image.

12. The apparatus of claim 8, wherein 2D sequential Gaussian simulation is performed by computing a kriging mean and variance to fit a variogram of hard data to obtain a probabilistic distribution of a respective simulation data point.

13. The apparatus of claim 8, wherein results of iterative 2D sequential gaussian simulation are combined to obtain the 3D seismic velocity model.

14. The apparatus of claim 8, wherein the well log sample points are depth and seismic velocity data points.

15. A system, comprising:
one or more memory modules;
one or more hardware processors communicably coupled to the one or more memory modules, the one or more hardware processors configured to execute instructions stored on the one or more memory models to perform operations comprising:
generating a three-dimensional (3D) seismic velocity model using sequential gaussian simulation based on interpolated well log sample points and seismic images, wherein two-dimensional (2D) sequential gaussian simulation is iteratively performed at respective depths;
executing forward modeling simulations on the seismic velocity model to generate primaries and multiples of wavelets associated with the seismic velocity model; and
combining the primaries and the multiples of wavelets with noise to generate augmented seismic data.

16. The system of claim 15, wherein the forward simulations are performed by summing reflections of velocity models generated by sequential gaussian simulation.

17. The system of claim 15, comprising generating the interpolated well log sample points by performing image guided interpolation using the seismic images.

18. The system of claim 15, wherein the interpolated well log sample points are generated by extracting structural information that guides the interpolation from a respective seismic image.

19. The system of claim 15, wherein 2D sequential Gaussian simulation is performed by computing a kriging mean and variance to fit a variogram of hard data to obtain a probabilistic distribution of a respective simulation data point.

20. The system of claim 15, wherein results of iterative 2D sequential gaussian simulation are combined to obtain the 3D seismic velocity model.
